(19) United States
(12) Patent Application Publication
(10) Pub. No.: US 2025/0069933 A1
(43) Pub. Date: Feb. 27, 2025

(54) ELECTROSTATIC CHUCK

(71) Applicant: TOTO LTD., Fukuoka (JP)

(72) Inventors: Masafumi IKEGUCHI, Fukuoka (JP); Kouta KOBAYASHI, Fukuoka (JP); Yutaka MOMIYAMA, Fukuoka (JP)

(73) Assignee: TOTO LTD., Fukuoka (JP)

(21) Appl. No.: 18/806,123

(22) Filed: Aug. 15, 2024

(30) Foreign Application Priority Data
Aug. 21, 2023 (JP) 2023-133997

(51) Int. Cl. H01L 21/683

(52) U.S. Cl. CPC H01L 21/6833

(57) ABSTRACT

An electrostatic chuck 10 includes a dielectric substrate 100, a base plate 200, and a joining layer 300 which joins the dielectric substrate 100 and the base plate 200. The joining layer 300 is obtained by containing a plurality of particulate filler materials 320 inside resin 310. The content of the filler materials 320 in the joining layer 300 is equal to or lower than 70% by weight.

### CROSS-REFERENCE TO RELATED APPLICATION

This application is based upon and claims the benefit of priority from Japanese Patent Application No. 2023-133997 filed on Aug. 21, 2023, the entire contents of which are incorporated herein by reference.

### BACKGROUND

The present invention relates to an electrostatic chuck.

In a semiconductor manufacturing apparatus such as an etching apparatus, an electrostatic chuck is provided as an apparatus for attracting and holding a wafer such as a silicon wafer to be processed. The electrostatic chuck includes a dielectric substrate to which an attraction electrode is provided, and a base plate which supports the dielectric substrate, and has a configuration in which these are joined to each other. The attraction electrode is generally built in the dielectric substrate, but a base plate made of a metal may be used as the attraction electrode. When a voltage is applied to the attraction electrode, an electrostatic force is generated, and the wafer placed on the dielectric substrate is attracted and held.

During the process, the temperature of the wafer increases when the wafer is exposed to plasma, and the temperature of the dielectric substrate also increases. In a semiconductor manufacturing apparatus of recent years, energy incidents on the wafer and the dielectric substrate during the process have increased. For this reason, the base plate has been required to have higher cooling performance than before. A joining layer which joins the dielectric substrate and the base plate has been required to have higher heat transfer performance than before.

As a method of increasing the heat transfer performance (specifically, a thermal conductivity) of the joining layer, for example, as illustrated in International Publication No. WO 2009/107701, particulate filler materials which are referred to as “fillers” are generally contained inside the joining layer. For example, when the joining layer is obtained by causing a silicone adhesive to be cured, particles of alumina or the like which has a thermal conductivity higher than that of silicone present in the surroundings are used as the filler materials.

The content of the filler materials to be contained in the joining layer is appropriately adjusted according to the heat transfer performance needed for the joining layer. As described above, since the joining layer has been demanded to have the higher heat transfer performance in recent years, it is conceivable that the content of the filler materials to be contained in the joining layer further increases.

However, according to an experiment conducted by the inventors of the present invention, a new finding has been attained that in a low temperature environment where a part of the joining layer is cooled down to −60° C. or lower, a relationship between the content of the filler materials in the joining layer and a flexibility becomes nonlinear, and when the content of the filler materials exceeds a predetermined amount, the flexibility abruptly decreases. When the flexibility of the joining layer decreases, peeling of the joining layer is likely to occur along with a thermal expansion difference between the dielectric substrate and the base plate.

The present invention has been made in view of the above-described issue, and is aimed to provide an electrostatic chuck which can suppress peeling of a joining layer.

### SUMMARY

To address the above-described issue, an electrostatic chuck according to an aspect of the present invention includes a dielectric substrate, a base plate, and a joining layer which joins the dielectric substrate and the base plate. The joining layer is obtained by containing a plurality of particulate filler materials inside resin. The content of the filler materials in the joining layer is equal to or lower than 70% by weight.

According to an experiment conducted by the inventors of the present invention or the like, a new finding has been attained that in a low temperature environment where the joining layer is cooled down to −60° C. or lower, when the content of the filler materials in the joining layer exceeds 70% by weight, a flexibility of the joining layer abruptly decreases. Therefore, when the content of the filler materials is set to be equal to or lower than 70% by weight as described above, it is possible to sufficiently secure the flexibility of the joining layer even in the low temperature environment, and it is possible to reduce a probability of occurrence that the joining layer is peeled off.

According to the aspect of the present invention, it is possible to provide the electrostatic chuck which can suppress the peeling of the joining layer.

### BRIEF DESCRIPTION OF THE DRAWINGS

FIG. 1 is a cross sectional view schematically illustrating a configuration of an electrostatic chuck according to the present embodiment;

FIG. 2 is a cross sectional view schematically illustrating an inside of a joining layer;

FIG. 3 is a diagram illustrating the relationship between the content of filler materials in the joining layer and a critical shear strain of the joining layer; and

FIG. 4 is a diagram illustrating the relationship between the content of the filler materials in the joining layer and the critical shear strain of the joining layer.

### DETAILED DESCRIPTION OF THE INVENTION

Hereinafter, the present embodiment will be described with reference to the accompanying drawings. To facilitate understanding of the description, same components in the respective drawings are denoted by the same reference signs as much as possible to omit repeated description.

An electrostatic chuck 10 according to the present embodiment is configured to attract and hold a wafer W set as a process target by an electrostatic force inside a semiconductor manufacturing apparatus which is not illustrated in the drawing such as, for example, an etching apparatus. The wafer W is, for example, a silicon wafer. The electrostatic chuck 10 may be used in an apparatus other than the semiconductor manufacturing apparatus.

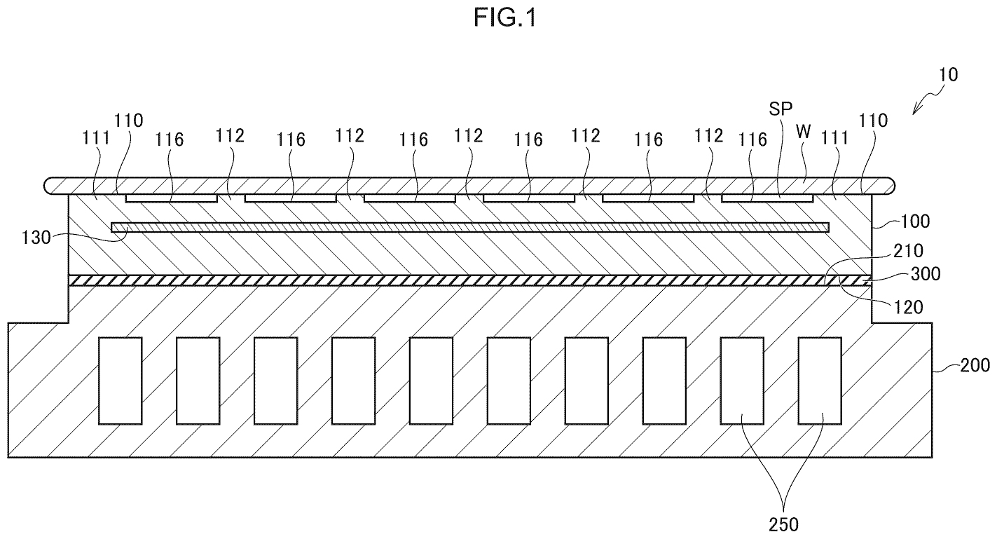

FIG. 1 is a cross sectional view schematically illustrating a configuration of the electrostatic chuck 10 in a state in which the wafer W is attracted and held. The electrostatic chuck 10 includes a dielectric substrate 100, a base plate 200, and a joining layer 300.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via the joining layer 300 described below.

An attraction electrode 130 is embedded inside the dielectric substrate 100. The attraction electrode 130 is a thin planar layer made of a metallic material such as, for example, tungsten, and is arranged so as to be parallel to the surface 110. In addition to tungsten, as a material of the attraction electrode 130, molybdenum, platinum, palladium, or the like may be used. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various configurations in related arts can be adopted. The single attraction electrode 130 may be provided as so-called a “monopolar” electrode as in the present embodiment, but may also include two attraction electrodes as so-called “bipolar” electrodes.

As illustrated in FIG. 1, a space SP is formed between the dielectric substrate 100 and the wafer W. When a process such as film formation is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 becomes a part of the surface 110, and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 122 to be provided. The plurality of dots 122 are substantially uniformly distributed and arranged on the placement surface of the dielectric substrate 100. An upper end of each of the dots 112 becomes a part of the surface 110, and abuts against the wafer W. By providing the plurality of thus configured dots 112, warping of the wafer W is reduced.

The base plate 200 is a substantially disk-shaped member which supports the dielectric substrate 100. The base plate 200 is made of a metallic material such as, for example, aluminum. A surface 210 on the upper side in FIG. 1 in the base plate 200 serves as a “surface to be joined” which is joined to the dielectric substrate 100 via the joining layer 300.

A coolant flow path 250 through which a coolant flows is formed inside the base plate 200. When a process such as film formation is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, the joining layer 300, and the base plate 200, and the heat is exhausted to the outside together with the coolant.

An insulating film may be formed on a surface of the base plate 200. As the insulating film, for example, an alumina film formed by thermal splaying can be used. When the surface of the base plate 200 is covered by the insulating film, it is possible to increase a withstand voltage of the base plate 200.

The joining layer 300 is a layer provided between the dielectric substrate 100 and the base plate 200 to join those components. According to the present embodiment, the joining layer 300 is formed by causing a silicone adhesive to be cured. The joining layer 300 may be obtained by causing an adhesive having a fluidity to be cured as in the present embodiment, but an adhesive sheet which has been solid from the beginning may be heated and then cured to obtain the joining layer 300.

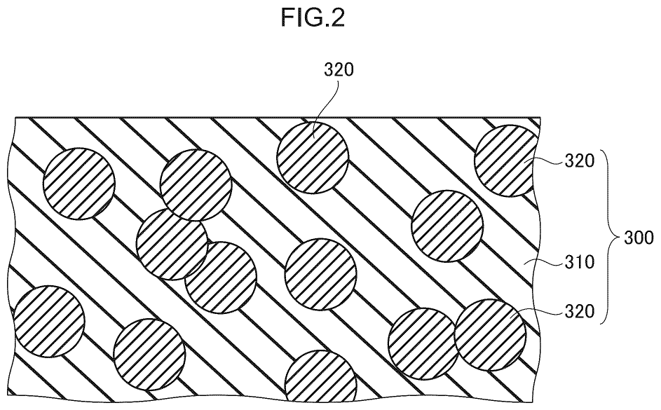

As illustrated in FIG. 2, particulate filler materials 320 are distributed to be arranged inside the joining layer 300. Resin which fills surrounding areas of the filler materials 320 will be also hereinafter referred to as “resin 310”. The resin 310 is silicone according to the present embodiment, but may also be a resin material other than silicone such as, for example, polyimide. It can be mentioned that the joining layer 300 having such a configuration is a layer obtained by containing a plurality of filler materials 320 inside the resin 310. It is noted that since FIG. 2 is a schematic drawing, an arrangement density, a distribution, and the like of the filler materials 320 in the resin 310 are different from those in actuality.

The filler materials 320 contain alumina as a major component. A material other than alumina may be used as the material of the filler materials 320 as long as the material has a thermal conductivity higher than that of the resin 310. For example, a material containing aluminum nitride (AlN), silicon carbide (SiC), silicon dioxide (SiO₂), or the like as a major component may be used to form the filler materials 320.

As illustrated in FIG. 2, a shape of the filler materials 320 is spherical, and a diameter of each of the filler materials 320 is approximately the same. The diameter of the filler material 320 is preferably sufficiently smaller than a total thickness of the joining layer 300.

The filler materials 320 are also so-called “fillers” or the like, and are contained inside the resin 310 for a purpose of increasing the thermal conductivity of the joining layer 300. As the content of the filler materials 320 is increased, the thermal conductivity of the joining layer 300 can be further increased. The content of the filler materials 320 is appropriately adjusted according to the heat transfer performance needed for the joining layer 300.

In a semiconductor manufacturing apparatus of recent years, energy incidents on the wafer W and the dielectric substrate 100 during the process have increased. For this reason, the joining layer 300 which joins the dielectric substrate 100 and the base plate 200 has been needed to have the higher heat transfer performance than before. It is conceivable that the content of the filler materials 320 in the joining layer 300 further increases from now on.

The inventors of the present invention have been conducting an intensive research focusing on a relationship between the content of the filler materials 320 and a flexibility of the joining layer 300. According to an experiment and the like conducted by the inventors of the present invention, a new finding has been attained that in a low temperature environment where a part of the joining layer 300 is cooled down to −60° C. or lower, the relationship between the content of the filler materials 320 in the joining layer 300 and the flexibility becomes nonlinear, and when the content of the filler materials 320 exceeds a predetermined amount, the flexibility abruptly decreases.

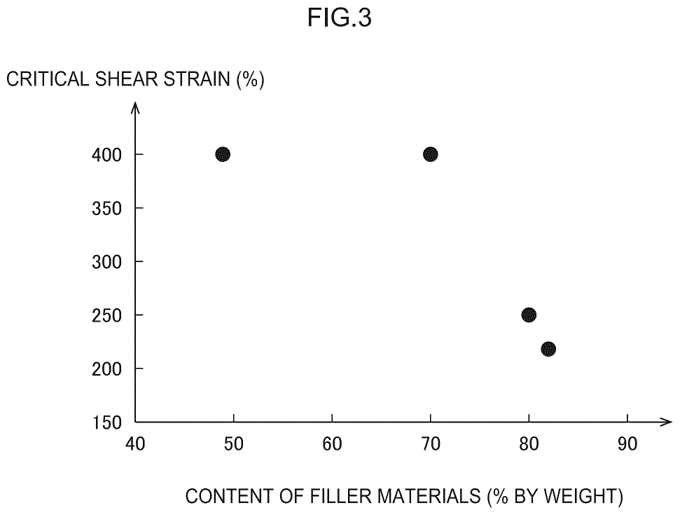

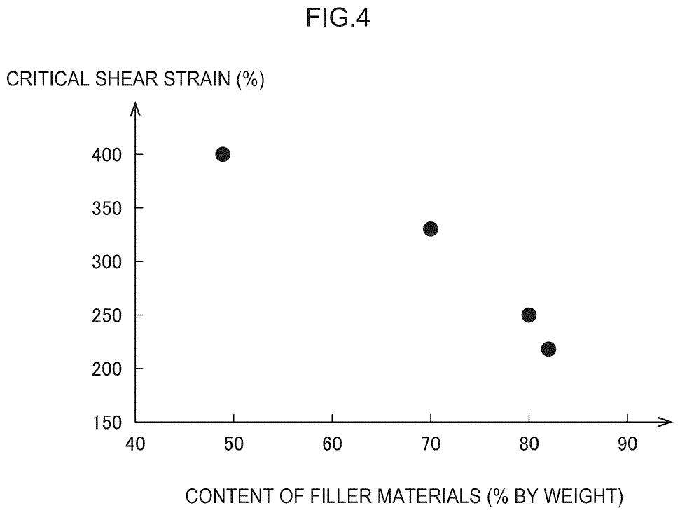

FIG. 3 and FIG. 4 illustrate results of measurements on a relationship between the content (horizontal axis) of the filler materials 320 in the joining layer 300 and a critical shear strain (vertical axis) of the joining layer 300. Herein, the “content of filler materials 320” shown on the horizontal axis in each of the drawings represents a percentage occupied by the filler materials 320 in the joining layer 300 by using a numerical value in “% by weight”. The “critical shear strain” shown on the vertical axis in each of the drawings refers to a maximum value of the shear strain generated in the joining layer 300 immediately before peeling occurs when a shear stress applied to the joining layer 300 is gradually increased. It can be mentioned that the critical shear strain is an index indicating the flexibility of the joining layer 300.

It is noted that each data illustrated in FIG. 3 and FIG. 4 is obtained by producing a plurality of test pieces having mutually different contents of the filler materials 320 in the joining layer 300, and carrying out a shear test pursuant to JISK6852-1994 on each of the test pieces. Each test piece was produced by joining a member made of a same material as the dielectric substrate 100 and a member made of a same material as the base plate 200 with the joining layer 300. A thickness of the joining layer 300 was set as 0.3 mm in each of the test pieces.

FIG. 3 illustrates the data at a time when a temperature of the entire test piece including the joining layer 300 is at −60° C. FIG. 4 illustrates the data at a time when the temperature of the entire test piece including the joining layer 300 is at −80° C.

As illustrated in FIG. 3 and FIG. 4, it was confirmed that as the content of the filler materials 320 in the joining layer 300 was increased, the critical shear strain of the joining layer 300 further decreased. It is noted however that when the content of the filler materials 320 was equal to or lower than 70% by weight, even when the content was increased, the critical shear strain was approximately constant or decreased only slowly.

On the other hand, it was confirmed that once and after the content of the filler materials 320 exceeded 70% by weight, when the content was further increased, the critical shear strain decreased significantly (more than before). In other words, it was confirmed that a gradient of a graph when each plot in FIG. 3 and FIG. 4 is connected changed at a boundary of the content at 70% by weight.

The inventors of the present invention conducted a plurality of experiments other than those illustrated in FIG. 3 and FIG. 4, but although data has some variability, a trend similar to the above-described trend was still confirmed. That is, such a trend was confirmed that in the low temperature environment where the joining layer 300 was cooled down to −60° C. or lower, when the content of the filler materials 320 exceeded approximately 70% by weight, the critical shear strain (in other words, the flexibility) of the joining layer 300 significantly decreased. When the flexibility of the joining layer 300 decreases, the peeling of the joining layer 300 is likely to occur along with a thermal expansion difference between the dielectric substrate 100 and the base plate 200.

As described above, in recent years, the energy incidents on the wafer W during the process have increased, and the base plate 200 is needed to have the higher cooling performance than before. For example, a coolant having a temperature at −60° C. or lower may be supplied to the coolant flow path 250 of the base plate 200. Since the temperature of the coolant further decreases along with an increase in plasma output or the like, there is also a possibility that a coolant having a temperature at approximately −100° C. may be supplied in the future. Therefore, the decrease in the flexibility of the joining layer 300 along with the increase in the content of the filler materials 320 may become the more serious issue from here on.

In view of the above, based on the above-described finding according to the present embodiment, the content of the filler materials 320 in the joining layer 300 is kept to be equal to or lower than 70% by weight. By adjusting the content of the filler materials 320 in this manner, the flexibility of the joining layer 300 can be sufficiently secured even in the low temperature environment, and it is possible to reduce the possibility that the peeling of the joining layer 300 occurs.

It is noted that a lower limit value of the content of the filler materials 320 may be appropriately set according to the heat transfer performance needed for the joining layer 300 or the like, and may be, for example, equal to or higher than 50% by weight.

If the thickness of the joining layer 300 is sufficiently increased, since the shear strain is absorbed even when the flexibility of the joining layer 300 decreases to a certain extent, the possibility that the peeling of the joining layer 300 occurs is lowered. However, in this case, the heat transfer performance of the joining layer 300 notably decreases. To sufficiently secure the heat transfer performance of the joining layer 300, the thickness of the joining layer 300 needs to be decreased to be set to 0.3 mm or lower, for example. In this manner, even in a case where the thickness of the joining layer 300 is decreased to secure the heat transfer performance, when the content of the filler materials 320 is set to be equal to or lower than 70% by weight as described above, the peeling of the joining layer 300 along with the decrease in the flexibility can be sufficiently suppressed.

The shape of the filler materials 320 may be spherical as illustrated in FIG. 2, but may be a shape other than the above. However, when some or all of the filler materials 320 were spherical, an advantage attained by keeping the content of the filler materials 320 to be equal to or lower than 70% by weight was confirmed more notably.

The content of the filler materials 320 in the joining layer 300 can be easily measured based on the weight of the filler materials 320 added to the adhesive before being cured.

The content of the filler materials 320 in the joining layer 300 can also be measured posteriori with regard to the electrostatic chuck 10 after the joining via the joining layer 300 is completed. For example, in a case where the resin 310 is silicone as in the present embodiment, after a silicone cleaner is used to dissolve the resin 310, a weight of the filler materials 320 remaining without being dissolved can be measured, and the content of the filler materials 320 can be calculated based on the weight. When the resin 310 is resin other than silicone, a chemical that may dissolve the resin may be used instead of the silicone cleaner.

The present embodiment has been described above with reference to the specific examples, but the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate;
a base plate; and
a joining layer which joins the dielectric substrate and the base plate, wherein
the joining layer is obtained by containing a plurality of particulate filler materials inside resin, and
a content of the filler materials in the joining layer is equal to or lower than 70% by weight.

2. The electrostatic chuck according to claim 1, wherein the resin is silicone.

3. The electrostatic chuck according to claim 1, wherein the filler materials contain alumina as a major component.

4. The electrostatic chuck according to claim 1, wherein a thickness of the joining layer is equal to or lower than 0.3 mm.

5. The electrostatic chuck according to claim 1, wherein a shape of at least a part of the filler materials is spherical.
